(19) United States
(12) Patent Application Publication
(10) Pub. No.: US 2007/0126014 A1
(43) Pub. Date: Jun. 7, 2007

(54) LIGHT-EMITTING ELEMENT WITH HETEROJUNCTION STRUCTURE

(75) Inventors: Ming-Han Liao, Taipei (TW); Cheng-Yeh Yu, Taipei (TW); Chee Wee Liu, Taipei (TW)

Correspondence Address: VOLPE AND KOENIG, P.C., UNITED PLAZA, SUITE 1600, 30 SOUTH 17TH STREET, PHILADELPHIA, PA, 19103, US

(73) Assignee: NATIONAL TAIWAN UNIVERSITY, Taipei (TW)

(21) Appl. No.: 11/536,025

(22) Filed: Sep. 28, 2006

(30) Foreign Application Priority Data
Dec. 1, 2005 (TW) 94142378

(51) Int. Cl. H01L 33/00; H01L 21/00

(52) U.S. Cl. 257/94; 438/22; 438/47; 257/183

(57) ABSTRACT

A method for manufacturing a light-emitting element with a heterojunction of group IV is provided. The method comprises at least the steps of: (1) providing a silicon substrate having a first and a second surfaces; (2) forming a germanium layer on the first surface; (3) forming a cap layer on the germanium layer; (4) forming a oxidation layer on the cap layer; (5) forming a first conductive layer on the oxidation layer; (6) forming a second conductive layer on the second surface; and (7) respectively forming a conductive wire on the first and second conductive layers. The light-emitting element of MOS semiconductor manufactured by the abovementioned steps is characterized in the emission of long wavelength.

### FIELD OF THE INVENTION

The present invention relates to a light-emitting element of a group IV material, and more particularly to a light-emitting element of a silicon semiconductor with a silicon/germanium heterojunction structure and the manufacturing method thereof.

### BACKGROUND OF THE INVENTION

The Metal-Oxide-Silicon (MOS) semiconductor utilized to be an electroluminescence element has been disclosed in the Taiwanese patent (Issued No. 00456057) which was filed by one inventor of the present application. It is indicated in the mentioned patent that the structure of Metal-Oxide-Silicon and the properties of the energy band of silicon are used to let the radiative recombination between electrons and holes. In accordance with the above, the light-emitting diode with 1.1 μm wavelength, which is close to the band energy of silicon, is able to be produced and compatible to the current semiconductor manufacturing process. The above light-emitting diode with the Metal-Oxide-Silicon structure is applied based on the relationship between quantum mechanics and physical properties of semiconductor. The tunneling effect is enhanced while the oxidation layer is disposed in the thickness of nanometer, and a huge amount of electrons recombine with holes to produce photons through the structure of the silicon bandgap. However, the above thought is realized partially based on the current development of semiconductor manufacturing process, which makes the nanometer level manufacturing process easily be achieved. After the mentioned patent proves that the Metal-Oxide-Silicon has the electroluminance effect, various kinds of factors possible to improve its quantum efficiency, such as the temperature, the roughness, and other dielectric material additives have been developed subsequently.

On the other hand, as for the light-emitting diode technique using the long wavelength or near-infrared wavelength, the elements of group III and V have already been developed in the prior art. For example, the U.S. patent published in 1986 (U.S. Pat. No. 4,575,742), whose assignee is Mitsubushi Monsanto Chemical, disclosed that GaAs mixing with silicon is used to make the light-emitting diode with long wavelength and near-infrared wavelength. However, the inventor of the present invention further takes the advantage of the bandgap property of the group IV element interface to develop the metal-oxide-silicon semiconductor with long wavelength and near-infrared wavelength based on the inventor's long-term studies and experiences. Therefore, the present invention further broadens new application of the metal-oxide-silicon semiconductor in the photoelectric field.

From the above description, it is known that how to develop a light-emitting diode of MOS semiconductor with long wavelength and near-infrared wavelength has become a major problem to be solved. In order to overcome the drawbacks in the prior art, a light-emitting element of MOS semiconductor with a silicon/germanium heterojunction structure is provided. The particular design in the present invention not only solves the problems described above, but also is easy to be implemented. Thus, the invention has the utility for the industry.

### SUMMARY OF THE INVENTION

Since the general lattice constant of silicon is 5.43 A, if a hetero material whose lattice constant is different from silicon is grown in the heterojunction without defects, its bandgap depends on different level of stress due to the relative thickness, thereby changing the photoelectric property thereof. According to the above, a silicon/germanium alloy of group IV as a material for performing stress-strain engineering with silicon is provided in the present invention. If the lattice constant of silicon is set to be the same as that of silicon/germanium alloy, silicon is strained due to the extension stress because the lattice constant of silicon/germanium alloy is larger than that of silicon. Contrarily, if the lattice constant of silicon/germanium alloy is set to be the same as that of silicon, silicon/germanium alloy is strained due to the compressible stress because the lattice constant of silicon is smaller than that of silicon/germanium. At the room temperature, the energy bands of silicon and germanium are respectively 1.12 eV and 0.66 eV, and thus the bandgap structure of silicon/germanium heterojunction can be changed due to the different thickness therebetween. The light-emitting diode of MOS semiconductor capable of releasing long wavelength can be produced according to the above property.

In accordance with one aspect of the present invention, a method for manufacturing a light-emitting diode with a silicon/germanium heterojunction structure is provided. The method comprises the following steps: (1) providing a silicon substrate having a first and a second surfaces; (2) forming a germanium layer on the first surface; (3) forming a cap layer on the germanium layer; (4) forming an oxidation layer on the cap layer; (5) forming a first conductive layer on the oxidation layer; (6) forming a second conductive layer on the second surface; and (7) forming a first conductive line connected with the first conductive layer and a second conductive line connected with the second conductive layer.

Preferably, the silicon substrate is one of an n-type substrate and a p-type substrate.

Preferably, the silicon substrate has a crystal orientation being one selected from the group consisting of (100), (110), and (111).

Preferably, the germanium layer and the cap layer in the steps (2) and (3) are respectively formed by an epitaxy technique.

Preferably, the epitaxy technique is an ultra-high vacuum chemical vapor deposition.

Preferably, the relatively thin germanium layer has a thickness ranged from about 1 to 10 nanometers.

Preferably, the cap layer has a material selected from the group consisting of silicon, silicon/germanium alloy, germanium, and carbon.

Preferably, the oxidation layer in the step (4) is formed by a low temperature liquid oxidation to avoid material thermal budget.

Preferably, the first and second conductive layers in the steps (5) and (6) are respectively formed by an evaporation.

Preferably, the first and second conductive lines are made of gold.

In accordance with another aspect of the present invention, a light-emitting diode with a silicon/germanium heterojunction structure is provided. The light-emitting diode comprises at least a silicon substrate having a first and a second surfaces, a germanium layer formed on the first surface, a cap layer formed on the germanium layer, an oxidation layer formed on the cap layer, and a first and a second conductive layers respectively formed on the oxidation layer and the second surface for serving as conductive gates.

Preferably, a heterojunction interface is formed between the germanium layer and the cap layer for providing a bias between the first and second conductive layers to press the electrons of conduction band in the cap layers recombining with the holes of valance band in the germanium layer so as to illuminate.

Preferably, the silicon substrate is one of an n-type substrate and a p-type substrate.

Preferably, the silicon substrate has a crystal orientation being one selected from the group consisting of (100), (110), and (111).

Preferably, the germanium layer has a thickness ranged form about 1 to 10 nanometers

Preferably, the cap layer has a material selected from the group consisting of silicon, silicon/germanium alloy, germanium, and carbon.

Preferably, the first and second conductive layers are made of aluminum.

Preferably, the first and second conductive layers respectively have thicknesses of 15 and 200 nanometers.

Preferably, the first and second conductive layers respectively have a gold line for conductance.

The above aspects and advantages of the present invention will become more readily apparent to those ordinarily skilled in the art after reviewing the following detailed descriptions and accompanying drawings, in which:

### BRIEF DESCRIPTION OF THE DRAWINGS

FIGS. 1(A)-1(F) are schematic diagrams showing the manufacturing process of the light-emitting diode with a heterojunction structure according to the present invention;

FIG. 2 is a structural diagram of the light-emitting diode under TEM according to the present invention;

FIG. 3 is a schematic diagram showing the measurement of the basic property of the light-emitting diode according to the present invention;

FIG. 4 is a result of Raman frequency measurement for the light-emitting diode according to the present invention;

FIG. 5 is a distribution diagram between wavelength versus intensity of light at different temperatures according to the optical measurement of the light-emitting diode of the present invention; and

FIG. 6 is an energy band diagram in theory under a bias for the light-emitting diode of the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for the purposes of illustration and description only; it is not intended to be exhaustive or to be limited to the precise form disclosed.

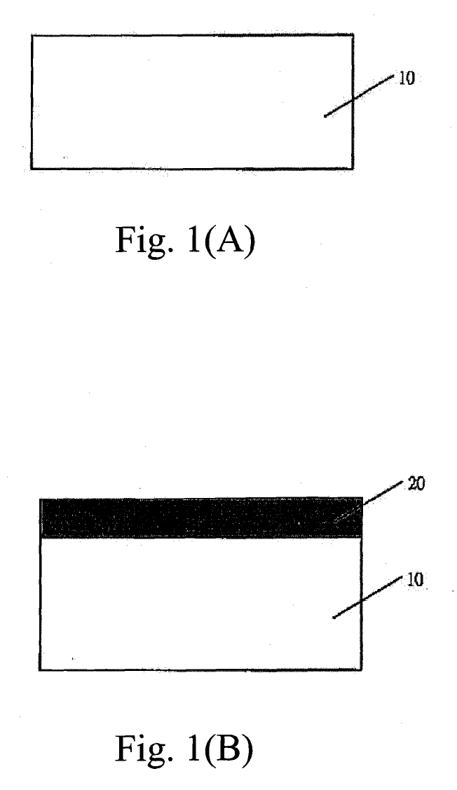

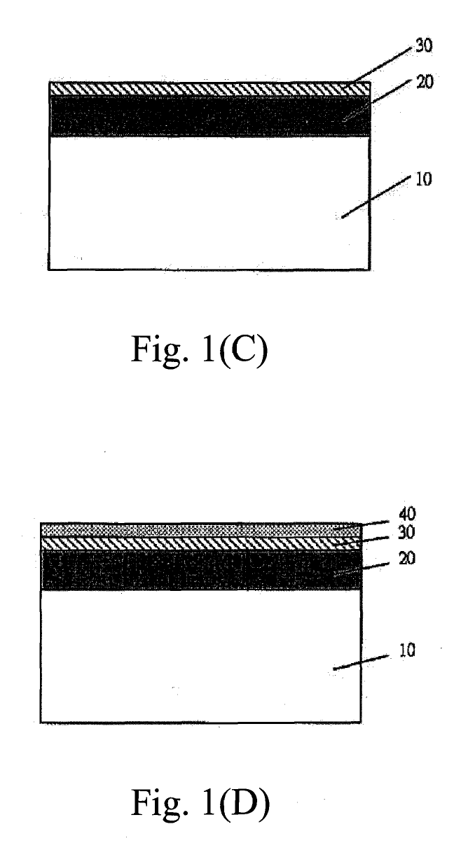

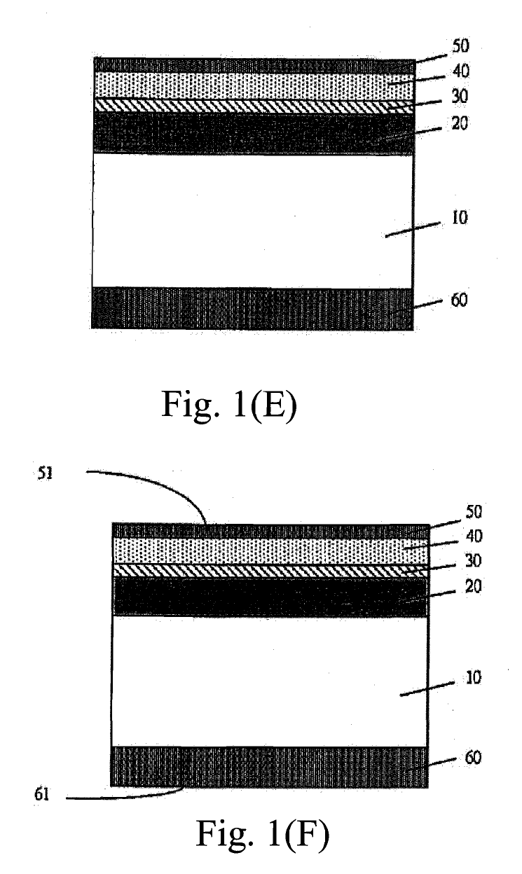

Please refer to FIGS. 1(A)-1(F), which show the manufacturing process of the light-emitting diode with a heterojunction structure having a material of group IV according to the present invention. The manufacturing process is illustrated in detail as follows. First, one of an n-type silicon substrate and a p-type silicon substrate 10 is provided, and the silicon substrate 10 has a crystal orientation being one selected from the group consisting of (100), (110), and (111). The upper surface of the silicon substrate 10 is defined as a light-emitting side, and the lower surface thereof is defined as a backlight side. Then, the germanium layer 20 and the cap layer 30 are respectively formed on the silicon substrate 10 by an epitaxy technique. The germanium layer 20 has a thickness ranged from about 1 to 10 nanometers, and the cap layer 30 has a thickness of 1 nm that can be made of a material selected from the group consisting of silicon, silicon/germanium alloy, germanium, and carbon. Next, an oxidation layer 40 is formed on the cap layer 30 by a formation technique of the oxidation layer compatible to the current semiconductor manufacturing process, such as a low temperature liquid oxidation to avoid thermal budget. Next, a first conductive layer 50 having a thickness of 15 nm and a second conductive layer 60 having a thickness of 200 mn are respectively formed on the oxidation layer 40 and the lower surface of the silicon substrate 10 by a surface formation technique, such as an evaporation. Further, the first conductive layer 50 and the second conductor layer 60 serve as conductive gates such that the light-emitting diode with a heterojunction structure having a material of group IV of the present invention is accomplished. Besides, in a preferred embodiment of the present invention, a conductive wire 51 and a conductive wire 61, such as a golden line, are respectively connected to the first conductive layer 50 and the second conductive layer 60 via a conductive contact, such as a silver gel. The above conductive wire is used to drive the light-emitting diode through the external electrical power.

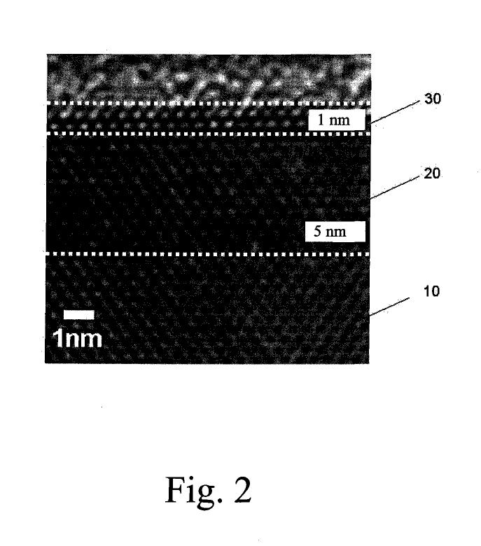

Please refer to FIG. 2, which shows a structural diagram of the section of the light-emitting diode with a heterojunction having a material of group IV under high-resolution TEM according to the present invention. From the above, it is known that the silicon substrate 10 is a p-type one as a base, and the upper surface thereof is a light-emitting surface. The germanium layer 20, the cap layer 30, and the oxidation layer 40 are sequentially formed on the silicon substrate 10. Besides, a perfect and high-quality silicon/germanium heterojunction having a material of group IV can be identified under TFM. In the orientation of (001), the p-type silicon substrate is formed well and is suitable for the designs of the nanoquantum well and the cap layer structure.

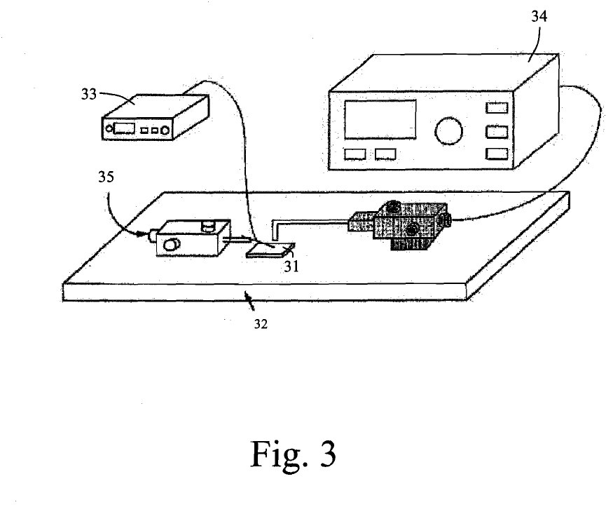

Please refer to FIG. 3, which is a schematic diagram showing the measurement of the basic property of the light-emitting diode sample according to the present invention. As illustrated in FIG. 3, first of all, the chip 31 including the light-emitting diode is fixed on a working station 32. Then, a power supply 33 is provided to guide the external electric force into the conductive layers at both sides of the light-emitting diode so as to drive it. Simultaneously, a monochromator and a photo detector are placed over the light-emitting surface of the light-emitting diode, and the base supporting the chip is controlled in the condition of variable temperatures so as to perform optical spectrum measurements, via a spectrum analyzer 34, under different temperatures. Besides, the measurement of the stress, the roughness, and the interface quality of the light-emitting diode can be performed via a probe 35.

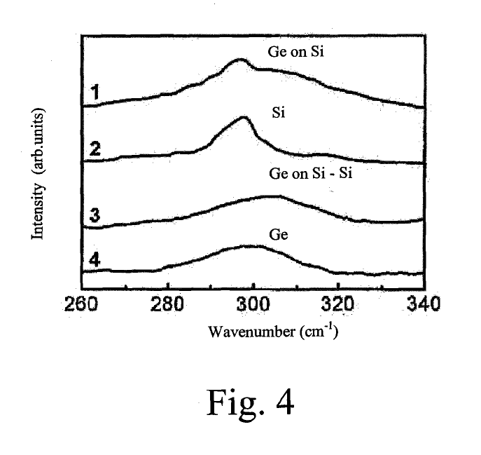

Please refer to FIG. 4, which shows a result of Ramen frequency measurements for the light-emitting diode according to the present invention. The light-emitting diode produces different stress-strain relations depending on the variable lattice constant of silicon/germanium heterojunction so as to change the bandgap structure thereof for providing a mechanism of spreading the infrared light source. By means of the analysis of Raman frequency measurements, the distributed stress-strain relations in the internal light-emitting diode are known based on the changes of oscillation frequency between atoms. In accordance with Lorenz model to simulate the Ramen waveform of the SiGe heterostructure, it is known that the value of the stress in the quantum well is about 4% of dual-axial compressive stress, and the Ge concentration in SiGe epi-layer is about 80%, due to the Si/Ge interdiffusion.

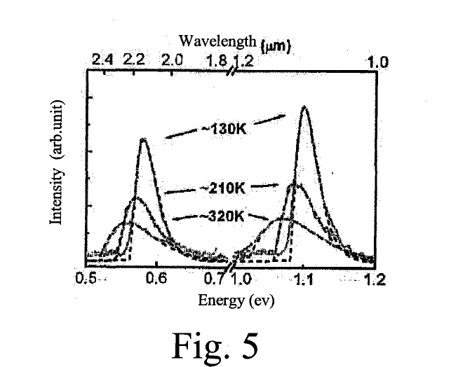

Please refer to FIG. 5, which shows a distribution diagram between wavelength versus intensity of light at different temperatures according to the optical measurement of the light-emitting diode of the present invention. The bandgap structure of the silicon/germanium interface is identified through the measurement of the optical signal. While there is a bias, electrons tunnel through the oxidation layer to approach the neighborhood of the silicon/germanium interface. Then, the electrons tunneling through the oxidation layer recombine with the holes in the quantum well to generate light, which is proved experimentally and in theory based on the property of the bandgap. Therefore, this kind of metal-oxide-silicon semiconductor with a silicon/germanium heterojunction structure is able to generate the near-infrared light.

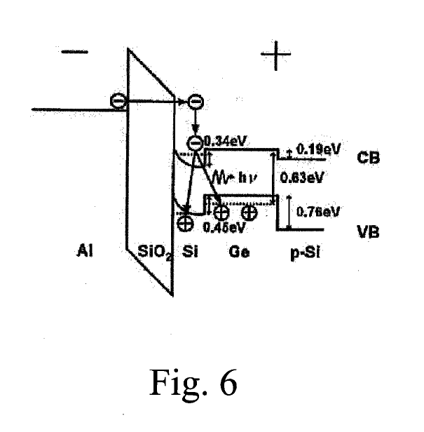

Please refer to FIG. 6, which shows an energy band diagram in theory under a bias for the light-emitting diode of the present invention. The theoretical value of stress corresponding to the bandgap structure can be calculated based on the silicon/germanium heterojunction structure. Therefore, the value of the strain in the germanium quantum well is calculated to be about 4% of compressible stress. The situation that electrons tunnel through the oxidation layer and recombine with the holes in the quantum well so as to illuminate while there exists a bias can be described based on the theoretical values of the bandgap structure. Simultaneously, the near infrared light source is able to be generated by this kind of MOS semiconductor with a silicon/germanium heterojunction structure of group IV based on the structure of the bandgap. Furthermore, a longer wavelength, such as the light source of intermediate and far infrared wavelength, can be developed through altering the structure of the bandgap to generate the different stress-strain relations according to the present invention.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. A method for manufacturing a light-emitting element with a heterojunction structure, comprising:
(1) providing a silicon substrate having a first and a second surfaces;
(2) forming a germanium layer on the first surface;
(3) forming a cap layer on the germanium layer;
(4) forming an oxidation layer on the cap layer;
(5) forming a first conductive layer on the oxidation layer;
(6) forming a second conductive layer on the second surface; and
(7) forming a first conductive line connected with the first conductive layer and a second conductive line connected with the second conductive layer.

2. The method of claim 1, wherein the silicon substrate is one of an n-type substrate and a p-type substrate.

3. The method of claim 1, wherein the silicon substrate has a crystal orientation being one selected from the group consisting of (100), (110), and (111).

4. The method of claim 1, wherein the germanium layer and the cap layer in the steps (2) and (3) are respectively formed by an epitaxy technique.

5. The method of claim 4, wherein the epitaxy technique is an ultra-high vacuum chemical vapor deposition.

6. The method of claim 1, wherein the germanium layer has a thickness ranged from about 1 to 10 nanometers.

7. The method of claim 1, wherein the cap layer has a material selected from the group consisting of silicon, silicon/germanium alloy, germanium, and carbon.

8. The method of claim 1, wherein the oxidation layer in the step (4) is formed by a low temperature liquid oxidation.

9. The method of claim 1, wherein the first and second conductive layers in the steps (5) and (6) are respectively formed by a respective evaporation.

10. The method of claim 1, wherein the first and second conductive lines are made of gold.

11. A light-emitting element with a heterojunction structure, comprising:
a silicon substrate having a first and a second surfaces;
a germanium layer formed on the first surface;
a cap layer formed on the germanium layer;
an oxidation layer formed on the cap layer; and
a first and a second conductive layers respectively formed on the oxidation layer and the second surface for serving as conductive gates.

12. The light-emitting element of claim 11, wherein a heterojunction interface is formed between the germanium layer and the cap layer.

13. The light-emitting element of claim 11, wherein the silicon substrate is one of an n-type substrate and a p-type substrate.

14. The light-emitting element of claim 11, wherein the silicon substrate has a crystal orientation being one selected from the group consisting of (100), (110), and (111).

15. The light-emitting element of claim 11, wherein the germanium layer has a thickness ranged form about 1 to 10 nanometers.

16. The light-emitting element of claim 11, wherein the cap layer has a material selected from the group consisting of silicon, silicon/germanium alloy, germanium, and carbon.

17. The light-emitting element of claim 11, wherein the first and second conductive layers are made of aluminum.

18. The light-emitting element of claim 11, wherein the first and second conductive layers respectively have thicknesses of 15 and 200 nanometers.

19. The light-emitting element of claim 11, wherein the first and second conductive layers respectively have a gold line for conductance.
